(19) United States
(12) Patent Application Publication
(10) Pub. No.: US 2017/0069497 A1
(43) Pub. Date: Mar. 9, 2017

(54) PLASMA ETCHING METHOD

(71) Applicant: TOKYO ELECTRON LIMITED, Tokyo (JP)

(72) Inventor: Hiroki AMEMIYA, Fuchu City (JP)

(73) Assignee: TOKYO ELECTRON LIMITED, Tokyo (JP)

(21) Appl. No.: 15/309,135

(22) PCT Filed: May 1, 2015
(86) PCT No.: PCT/JP2015/063065

§ 371 Date: Nov. 4, 2016

(30) Foreign Application Priority Data
May 7, 2014 (JP) 2014-096059

(51) Int. Cl. H01L 21/04; H01L 21/308; H01L 29/423; H01J 37/32; H01L 21/67; H01L 21/683; H01L 21/687; H01L 21/3065; H01L 29/16

(52) U.S. Cl. CPC H01L 21/0475; H01L 21/3065; H01L 21/3081; H01L 29/4236; H01L 29/1608; H01L 21/67069; H01L 21/6833; H01L 21/67103; H01L 21/68742; H01L 21/68735; H01J 37/32449; H01J 37/32715; H01J 37/32568; H01J 2237/334

(57) ABSTRACT

A method for plasma etching a SiC film that is formed with an etching mask and is on a wafer (W), wherein a processing vessel is supplied with a mixed gas comprising a noble gas and a process gas that includes SF₆ gas and O₂ gas, and the SiC film is etched by the mixed gas plasma. This etching is conducted using a magnetron RIE device.

### TECHNICAL FIELD

This application is based on and claims priority from Japanese Patent Application No. 2014-096059 filed on May 7, 2014, with the Japan Patent Office, the disclosure of which is incorporated herein in its entirety by reference.

The present disclosure relates to a method for plasma etching an object to be processed.

### BACKGROUND

In power devices using a semiconductor, a power device using a trench-type gate has been recently the mainstream of a structure for the miniaturization and the on-resistance reduction of the power device. The trench-type gate is generally formed by dry etching using plasma.

In recent, it has been expected to use silicon carbide (SiC) as of the material of the power device for implementing a higher breakdown voltage and a lower on-resistance than those of conventional silicon. However, when forming a trench in SiC by dry etching, problems are caused in that the bottom of the trench is not flat, and small trenches, so-called microtrenches, are formed in the opposite ends of the trench.

Thus, Patent Document 1 suggests a method of suppressing the microtrenches by using inductively coupled plasma for the dry etching and appropriately setting a flow rate ratio of etching gases, a pressure inside a processing container, and a generation power of the inductively coupled plasma. According to the method of Patent Document 1, a SiC substrate may be etched while suppressing the generation of micro-trenches, by using a gas mixture of, for example, SF₆, O₂, and Ar as the etching gases and setting the pressure inside the processing container to 2.5 Pa to 2.7 Pa, and the generation power of plasma to a range of 500 W to 600 W.

### PRIOR ART DOCUMENT

### Patent Document

Patent Document 1: Japanese Patent Laid-Open Publication No. 2009-188221

### DISCLOSURE OF THE INVENTION

### Problems to be Solved

However, when the etching is performed by the method of Patent Document 1, there have been problems in that the reproducibility in an etching rate or a trench shape is insufficient, and the processing stability is unsatisfactory.

Further, since the SiC has the face orientation dependency of a crystal in electron mobility, it is desirable that the angle of a side wall of a trench formed by the etching is closer to the vertical. However, the limit of the side wall angle of the trench is currently about 87°, and further improvement in the trench shape is being demanded.

The present disclosure has been made in view of the foregoing circumstances, and an object thereof is to perform stable plasma etching on a SiC film and process the SiC film into a desired shape.

### Means to Solve the Problems

In order to achieve the above-described object, the present disclosure provides a method for plasma etching a SiC film formed thereon with an etching mask within a processing container. A gas mixture obtained by mixing a processing gas containing SF₆ gas and O₂ gas and a rare gas with each other is supplied into the processing container, the SiC film is etched by plasma of the gas mixture, and the etching is performed using a magnetron RIE apparatus.

In general, the stability of the plasma etching is improved as the pressure inside the processing chamber or the plasma density on a substrate is high. Further, in order to make the trench shape closer to the vertical, it is required that the plasma be caused to be generated in a position close to the substrate and reach the substrate without deactivating radicals or ions in the plasma. The inventors of the present disclosure have intensively examined these points, and obtained the knowledge that high density plasma may be generated, and the plasma may be generated in a position close to a substrate by using the magnetron RIE apparatus, as compared to using an inductively coupled plasma. According to the inventors, it is presumed that since the thickness of a plasma sheath may be made thin by using the magnetron RIE apparatus, as compared to using the inductively coupled plasma, high density plasma may be generated in a position close to the substrate.

The present disclosure was made based on the knowledge above, and supplies a gas mixture obtained by mixing a processing gas containing SF₆ gas and O₂ gas and a rare gas such as, for example, Ar or He gas with each other, and etching the SiC film with plasma of the gas mixture by using the magnetron RIE apparatus, so that the high density plasma may be generated in a position close to the substrate inside the processing container. As a result, the stability of the plasma etching is improved, and furthermore, the plasma may be caused to reach the substrate without deactivating radicals or ions in the plasma, so that the generation of microtrenches may be suppressed, and the angle of the trench side wall may be made closer to the vertical. Thus, according to the present disclosure, stable plasma etching may be performed on the SiC film, and the SiC film may be processed into a desired shape.

Another aspect of the present disclosure is a method for plasma etching a SiC film formed thereon with an etching mask within a processing container, and the method is characterized in that a processing gas containing HBr gas is supplied into the processing container, the SiC film is etched with plasma of the processing gas, the pressure inside the processing container is kept at 2.0 Pa to 13.3 Pa during the etching, the etching is performed using the magnetron RIE apparatus, and the plasma of the processing gas is generated by a high frequency power of 400 W to 2,000 W.

### Effect of the Invention

According to the present disclosure, stable plasma etching may be performed on the SiC film, and the SiC film may be processed into a desired shape.

### BRIEF DESCRIPTION OF THE DRAWINGS

FIG. 1 is a vertical sectional view illustrating an outline of a plasma processing apparatus according to an exemplary embodiment.

FIG. 2 is a sectional view schematically illustrating a state where an etching mask is formed on a SiC film on a wafer.

FIG. 3 is a sectional view schematically illustrating a state of an etched SiC film.

FIG. 4 is a vertical sectional view schematically illustrating a trench shape.

FIG. 5 is a vertical sectional view schematically illustrating a trench shape.

FIG. 6 is a vertical sectional view schematically illustrating a trench shape.

### DETAILED DESCRIPTION TO EXECUTE THE INVENTION

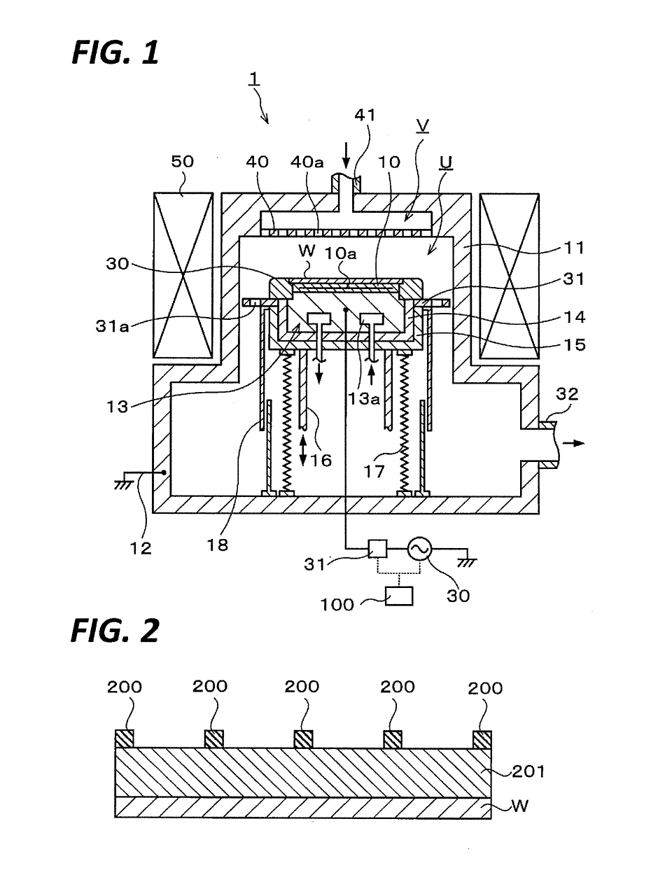

Hereinafter, exemplary embodiments of the present disclosure will be described with reference to the accompanying drawings. FIG. 1 is a vertical sectional view illustrating an outline of a plasma processing apparatus 1 for performing plasma etching according to an exemplary embodiment. The plasma processing apparatus 1 in the present exemplary embodiment is a so-called magnetron RIE apparatus.

The plasma processing apparatus 1 includes a substantially cylindrical processing container 11 in which a wafer chuck 10 is provided as a placement table to place and hold thereon a wafer W which is a silicon substrate. The processing container 11 is formed of a conductive metal such as, for example, aluminum and is in a state of being electrically grounded by a grounding line 12. On the inner wall surface of the processing container 11, an aluminum oxide film layer (not illustrated) is formed by, for example, anodization in order to improve the plasma resistance.

The bottom surface of the wafer chuck 10 is supported by a susceptor 13 serving as a lower electrode. The susceptor 13 is formed of a conductive metal such as, for example, aluminum and in a substantially disc shape. An electrode (not illustrated) is provided inside the wafer chuck 10, and the wafer W may be attracted and held by an electrostatic force generated when a DC voltage is applied to the electrode. In addition, a heater 10a is provided inside the wafer chuck 10 so that the wafer W held on the wafer chuck 10 may be heated to a predetermined temperature through the wafer chuck 10. As the heater 10a, for example, an electric heater is used. In addition, a refrigerant path 13a is formed inside the susceptor 13, for example, in an annular shape to cause a refrigerant to flow therethrough. By controlling the temperature of the refrigerant supplied by the refrigerant path 13a, the temperature of the wafer chuck 10 may be controlled.

A portion of the susceptor 13 other than the surface facing the wafer chuck 10 is covered by an insulating member 14 formed of, for example, ceramics. The surface of the insulating member 14 opposite to the susceptor 10 is covered by a conducting member 15 formed of a conductive metal such as, for example, aluminum.

The susceptor 13 is configured to be vertically movable by lift mechanisms 16 connected to the bottom surface of the conducting member 15. A bellows 17 made of, for example, stainless steel is provided to extend downwardly from further outer portions of the bottom surface of the conducting member 15 than the portions thereof to which the lift mechanisms 16 are connected. The end of the bellows 17 opposite to the side connected to the conducting member 15 is connected to the bottom surface of the processing container 11. The above-described aluminum oxide film layer has been removed from the portion of the processing container 11 connected to the bellows 17. Accordingly, the conducting member 15 is grounded through the bellows 17 and the processing container 11. A bellows cover 17 is provided outside the bellows 17 to surround the bellows 17.

A high frequency power supply 20 is electrically connected to the susceptor 13 via a matcher 21 to supply a high frequency power to the susceptor 13, thereby generating plasma. The high frequency power supply 20 is configured to output a high frequency power having a frequency of, for example, 27 MHz to 100 MHz, especially for example, 40 MHz in the present exemplary embodiment. The matcher 21 matches the internal impedance and the load impedan of the high frequency power supply 20 with each other, and operates such that the internal impedance and the load impedance of the high frequency power supply 20 apparently match with each other when plasma is already generated within the processing container 11. The high frequency power supply 20 and the matcher 21 are connected to a controller 100 to be described later, and the operations thereof are controlled by the controller 100.

A focus ring 30 formed of, for example, an insulating material is provided at the outer peripheral portion of the wafer chuck 10 on the top surface of the susceptor 13, in order to improve the uniformity of the plasma processing. On the side surface of the insulating member 14 covering the susceptor 13, a substantially annular baffle plate 31 is disposed to be sandwiched between the bottom surface of the focus ring 30 and the top end of the conducting member 15. The baffle plate 31 is made of a conductive material such as, for example, surface-anodized aluminum. Further, the baffle plate 31 is electrically connected to the conducting member 15 by, for example, a conductive screw (not illustrated). Accordingly, the baffle plate 31 also is grounded through the bellows 17 and the processing container 11, like the conducting member 15. As a result, the inner wall of the processing container 11 above the baffle plate 31 and the baffle plate 31 function as a counter electrode of the susceptor 13 serving as a lower electrode. Accordingly, plasma may be confined in a processing space U surrounded by the top surface of the baffle plate 31 and the processing container 11.

In addition, a plurality of slits 31a are formed on the baffle plate 31 to pass through the baffle plate 31 in the thickness direction thereof. An exhaust pipe 32 connected to an exhaust mechanism (not illustrated) to exhaust the inside of the processing container 11 is connected to a lower portion of the processing container 11 below the baffle plate 31. Accordingly, the inside of the processing space U is exhausted from the exhaust pipe 32 through the slits 31a of the baffle plate 31 so as to be kept at a predetermined degree of vacuum.

A substantially disc-shaped upper electrode 40 is provided on the inner wall of the processing container 11 above the susceptor 13 serving as a lower electrode, i.e., opposite to the top surface of the wafer chuck 10. The upper electrode 40 is provided with a plurality of gas supply holes 40a that pass through the upper electrode 40 in the thickness direction thereof. A gas supply pipe 41 is connected to a gas diffusion chamber V surrounded by the upper electrode 40 and the processing container 11. A processing gas supply source (not illustrated) that supplies a predetermined processing gas and an additive gas supply source (not illustrated) that supplies an additive gas to be added to the processing gas are connected to the gas supply pipe 41. Accordingly, a gas mixture of the processing gas and the additive gas supplied into the gas diffusion chamber V through the gas supply pipe 41 is supplied into the processing space U through the gas supply holes 40a. The processing gas supplied from the gas supply source contains, for example, SF₆ gas and O₂ gas, and the additive gas supplied from the additive gas supply source may be, for example, Ar gas, He gas, Ne gas, Kr gas, Xe gas, or Rn gas. In the present exemplary embodiment, for example, the Ar gas is used as the additive gas.

At the position corresponding to the upper electrode 40 through the susceptor 13 outside the processing container 11, a ring magnet 50 is disposed in a ring shape concentrically with the processing container 11 to surround the plasma area formed between the susceptor 13 as a lower electrode and the upper electrode 40. A magnetic field may be applied to the processing space U between the baffle plate 31 and the upper electrode 42 by the ring magnet 50.

The plasma processing apparatus 1 is provided with the controller 100 as described above. The controller 100 is, for example, a computer, and includes a program storage unit (not illustrated). The program storage unit also stores a program to control, for example, the high frequency power supply 20 or the matcher 21 to operate the plasma processing apparatus 1.

Further, the program may be recorded in a computer-readable recording medium such as, for example, a hard disc (HD), a flexible disc (FD), a compact disc (CD), a magnet optical disc (MO), or a memory card, and installed from the recording medium to the controller 100.

The plasma processing apparatus 1 according to the present exemplary embodiment is configured as described above, and subsequently, plasma etching in the plasma processing apparatus 1 according to the present exemplary embodiment will be described.

In performing the plasma etching, a wafer W is first carried into the processing container 11 and placed and held on the wafer chuck 10. On the wafer W, a silicon oxide film 200 made of tetraethyl orthosilicate (TEOS) as a raw material is formed in advance as an etching mask, as illustrated in, for example, FIG. 2. As an object to be processed, a SiC film 201 is formed on the bottom surface of the silicon oxide film 200. Although FIG. 2 represents a state where the SiC film 201 is formed on the top surface of the wafer W, the aspect of the SiC film 201 is not limited to being formed on the wafer W, and for example, the wafer W itself may be a SiC substrate. In this case, the silicon oxide film 200 may be formed on the SiC substrate.

When the wafer W is held on the wafer chuck 10, the inside of the processing container 11 is exhausted through the exhaust pipe 32, and the processing gas is supplied into the processing chamber 11 from the gas supply pipe 41 at a predetermined flow rate. In this case, a gas mixture of SF₆/O₂/Ar is used as the processing gas. The flow rate ratio of the gas mixture may be 2 to 1:1 to 1.3:336.7 to 88, and in the present exemplary embodiment, the gases are supplied at flow rates of, for example, 8/10/880 sccm, respectively.

Further, a high frequency power of, for example, 500 W to 1,300 W, especially about 500 W in the present exemplary embodiment is continuously applied to the susceptor 13 serving as a lower electrode. Accordingly, the gas mixture supplied into the processing container 11 changes into plasma between the upper electrode 40 and the susceptor 13. In this case, a magnetic field having a magnetic flux density of about 100 gauss to 300 gauss (10 mT to 30 mT (Tesla)) is applied into the processing container 11 by the ring magnet 50. The plasma is confined between the upper electrode 40 and the susceptor 13 by the magnetic field of the ring magnet 50. Further, in this case, the pressure inside the processing container 11 is kept at 4.7 Pa to 13.3 Pa, and the wafer W on the wafer chuck 10 is kept at 60° C. to 80° C.

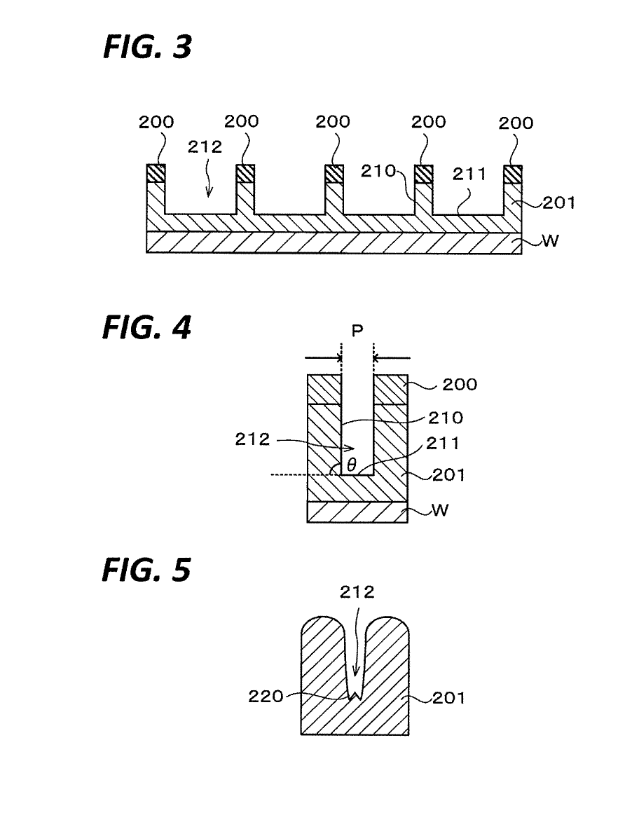

Then, as illustrated in FIG. 3, the SiC film 201 is etched using the silicon oxide film 200 as a mask by ions or radicals of the gas mixture generated by the plasma within the processing container 11. In this case, high density plasma is generated near the top surface of the wafer W by the magnetic field of the ring magnet 50. As a result, in addition to improving the stability of the plasma etching, the plasma may be caused to reach the wafer W without deactivating the radicals or the ions in the plasma. Hence, the generation of micro-trenches is suppressed, and the SiC film 201 may be etched into a desired shape. Specifically, as illustrated in FIG. 4, a trench 212 which has side walls substantially vertical to the top surface of the wafer W and a flat bottom surface 211 in parallel with the top surface of the wafer W may be formed. In addition to setting the flow rate ratio of the gas mixture of SF₆/O₂/Ar to 2 to 1:1 to 1.3:366.7 to 88, the high frequency power for the generation of plasma is set to a range of 500 W to 1,300 W, and the pressure inside the processing container 11 is set to a range of 4.7 Pa to 13.3 Pa which is higher than that of a conventional inductively coupled plasma apparatus, so that the SiC film 201 may be etched at a high etching rate of, for example, about 500 nm/min to 1,000 nm/mm.

After the SiC film 201 is etched to a predetermined depth of, for example, 1,700 nm to 2,600 nm, the application of the high frequency voltage by the high frequency power supply 20 is and stopped. Thereafter, the wafer W is carried out from the processing container 11, and the series of etching processes are ended.

According to the above-described exemplary embodiment, since the gas mixture obtained by mixing the processing gas containing SF₆ gas and O₂ gas and the Ar gas with each other is supplied into the processing container 11, and the SiC film 201 is plasma-etched by the plasma of the gas mixture by using the magnetron RIE apparatus as the plasma processing apparatus 1, high density plasma may be generated in a position near the wafer W within the processing container 11. As a result, in addition to improving the stability of the plasma etching, the plasma may be caused to reach the wafer W without deactivating the radicals or the ions in the plasma so that the generation of a micro-trench is suppressed, and the angle of the side walls 210 of the trench 212 may be made closer to the vertical. Thus, according to the present disclosure, stable plasma etching may be performed on the SiC film, and furthermore, the SiC film may be processed into a desired shape.

However, the SiC is a physically hard material and also a chemically stable material which is hard to be etched. Further, in the dry etching using the inductively coupled plasma as in Patent Document 1, since the etching rate is low, further improvement of the etching rate is demanded in view of the productivity.

In general, the power of the plasma or the flow rate of SF₆ as a reactive gas may be increased in order to improve the etching rate. However, according to Patent Document 1, microtrenches are generated when the etching rate is high. In view of this point, in the present exemplary embodiment, the SiC film 201 may be etched into a desired shape at the etching rate of, for example, about 500 nm/min to 1,000 nm/min, by setting the flow rate of the gas mixture of SF₆/O₂/Ar to 2 to 1:1 to 1.3:366.7 to 88, the high frequency power for the generation of plasma to a range of 500 W to 1,300 W, and the pressure inside the processing chamber 11 to a range of 4.7 Pa to 13.3 Pa which is higher than that in the conventional inductively coupled plasma apparatus.

Further, according to the inventors of the present disclosure, it was confirmed that the trench 212 having the more vertical side walls 210 and the flat bottom surface may be formed by maintaining the temperature of the wafer W, in other words, the temperature of the SiC film 201 at 60° C. to 80° C. during the plasma etching. In addition, in the conventional plasma etching, the temperature of the wafer W is set to fall between substantially −15° C. to 10° C.

In the above-described exemplary embodiment, the Ar gas is used as the additive gas to be added to the processing gas containing SF₆ gas and O₂ gas. However, as described above, instead of the Ar gas, another rare gas such as, for example, He gas may be used as the additive gas. According to the inventors of the present disclosure, it was confirmed by comparative experiments to be described later that the same effect as that in the case of using the Ar gas could be obtained even when the He gas was used as the additive gas. In addition, according to the inventors of the present disclosure, it was confirmed that deposits which were believed to have been derived from the gas mixture were attached to the side walls 210 of the etched SiC film 201. However, it was confirmed that the deposits were reduced when the He gas was used as the additive gas. Accordingly, it may be expected to form a trench 212 having the side walls 210 in a more favorable shape by using He as the additive gas.

In the above-described exemplary embodiment, the gas mixture of SF₆/O₂/Ar is used as a gas mixture for performing the plasma etching. However, a gas mixture obtained by additionally mixing SiF₄ gas with the gas mixture of SF₆/O₂/Ar may be used. As a result of the intensive study conducted by the inventors of the present disclosure through the comparative experiments to be described later, it was confirmed that by the mixture of the SiF₄ gas, the etching rate was improved, and furthermore, the side walls 210 of the trench 212 was made closer to the vertical.

In addition, as the gas mixture for performing the plasma etching, a gas mixture obtained by mixing HBr gas with the processing gas containing SF₆ gas and O₂ gas may be used. When the HBr gas is mixed, NF₃ gas may be used, instead of the SF₆ gas as the processing gas. As a result of the intensive study conducted by the inventors of the present disclosure through the comparative experiments to be described later, it was confirmed that when HBr/SF₆/O₂ is used as a gas mixture, the flow rate ratio of the gas mixture is favorably set to 13 to 20:0 to 3:1, and when the HBr gas is used, the SF₆ gas does not need to be necessarily used. In addition, when HBr/NF₃/O₂ is used as a gas mixture, the flow rate ratio of the gas mixture may be set to 13 to 20:3 to 5:1, and the gases may be supplied at flow rates of 205/45/15 sccm, respectively.

In applying a high frequency power when HBr/SF₆/O₂ or HBr/NF₃/O₂ is used as a gas mixture, a high frequency power of, for example, 400 W to 2,000 W, more specifically 400 W to 700 W is continuously applied to the susceptor 13 serving as a lower electrode by the high frequency power supply 20. Accordingly, the processing gas supplied into the processing container 11 changes into plasma between the upper electrode 40 and the susceptor 13. In this case, a magnetic field having a magnetic flux density of about 100 gauss to 300 gauss (10 mT to 30 mT (Tesla)) is applied into the processing container 11 by the ring magnet 50. The plasma is confined between the upper electrode 40 and the susceptor 13 by the magnetic field of the ring magnet 50. In addition, the pressure inside the processing container 11 is kept at 2.0 Pa to 6.7 Pa, more specifically 3.3 Pa to 6.7 Pa, and the wafer W on the wafer chuck 10 is kept at 60° C. to 80° C.

Then, the SiC film 201 is etched using the silicon oxide film 200 as a mask by ions or radicals of the gas mixture generated by the plasma within the processing container 11. In this case, since high density plasma is generated near the top surface of the wafer W by the magnetic field of the ring magnet 50, the SiC film 201 is etched at a high etching rate of, for example, 500 nm/min to 600 nm/min. In addition, since the pressure inside the processing container 11 is set to 2.0 Pa to 6.7 Pa which is higher than that in the conventional inductively coupled plasma apparatus, a processing by higher density plasma than that in the inductively coupled plasma apparatus may be performed.

Further, in the plasma processing apparatus 1 as the magnetron RIE apparatus, the SiC film 201 may be etched into a desired shape by using the gas containing the HBr gas as a processing gas, and setting the high frequency power for the plasma generation to the range of 400 W to 2,000 W. Specifically, as illustrated in FIG. 4, the trench 212 which has side walls 210 substantially vertical to the top surface of the wafer W and a flat bottom surface 211 in parallel with the top surface of the wafer W may be formed.

When the gas mixture of HBr/SF₆/O₂ or HBr/NF₃/O₂ is used, Ar may be added to the gas mixture. As a result of the intensive study conducted by the inventors of the present disclosure through the comparative experiments to be described later, it was confirmed that the shape of the trench 212 could be further improved by adding Ar. In addition, when the gas mixture of, for example, HBr/NF₃/O₂/Ar obtained by adding Ar is supplied, the flow rate ratio thereof may be set to 13 to 20/3 to 5/1/1 to 67. Instead of Ar, another rare gas may be added, and according to the inventors of the present disclosure, it was confirmed that the same effect as that in the case of using Ar could be obtained when the rare gas other than Ar was used.

### EXAMPLES

As an example, etching was performed on a SiC film formed on a wafer W while using the silicon oxide film 200 as an etching mask, and a verification test was conducted to verify the influence of the relevant conditions for the etching on, for example, the shape or the etching rate of the etched SiC film 201. In this case, the thickness of the silicon oxide film 200 as a mask was set to 1,200 nm to 2,000 nm, and a target value of the etching depth of the SiC film was set to 2,000 nm. SF₆/O₂/Ar was used as a processing gas, the pressure inside the processing container 11 was changed in a range of 4.7 Pa to 16.6 Pa, the power of the high frequency power supply 20 was changed in a range of 500 W to 1,500 W, and the set temperature of the wafer chuck 10 was changed in a range of 60° C. to 80° C.

The specific items verified in the verification test were the angle θ of the side walls 210 of the trench 212, the shape of the bottom surface 211 of the trench 212, and the etching rate of the trench 212. As for a favorable shape of the trench 212, the angle θ of the side walls 210 of the trench 212 is substantially 85° or more, and the bottom surface 211 of the trench 212 is flat without the generation of so-called microtrenches. In addition, since the SiC film has the crystal face orientation dependency depending on the electron mobility, the angle θ of the side walls 210 of the trench 212 is more favorably 90°.

First, a verification test was conducted for a case where the power of the high frequency power supply 20 was changed to 500 W, 100 W, 1,250 W, and 1,500 W (Verification Text 1). In this case, the pressure inside the processing container 11 was set to 6.7 Pa (50 mTorr), the set temperature of the wafer chuck 10 was 60° C., and the gas mixture of SF₆/O₂/Ar was supplied at a flow rate ratio of 8/10/880 sccm.

As a result of Verification Test 1, it was verified that when the power of the high frequency power supply 20 was changed to about 1,500 W, the angle θ of the side walls 210 was reduced, as compared to the power of 1,250 W or less, and further, microtrenches 220 were generated on the bottom surface 211 of the trench 212 as illustrated in FIG. 5. Meanwhile, it was verified that when the power of the high frequency power supply 20 was changed to about 1,250 W or less, the trench 212 could be formed into an optimum shape, that is, the shape in which the angle θ of the side walls 210 of the trench 212 was about 85° or more, and the bottom surface 211 of the trench 212 was flat without the generation of so-called microtrenches.

Subsequently, a verification test was conducted for a case where the pressure inside the processing container 11 was changed to 4.7 Pa, 6.7 Pa, 10.0 Pa, 13.3 Pa, and 16.6 Pa (Verification Test 2). In this case, the power of the high frequency power supply was set to 1, 200 W, the set temperature of the wafer chuck 10 was 60° C., and the gas mixture of SF₆/O₂/Ar was supplied at a flow rate ratio of 8/10/440 sccm.

As a result of Verification Test 2, it was verified that when the pressure inside the processing container 11 is changed to 4.7 Pa to 13.3 Pa, the trench 212 could be formed in an optimum shape, that is, the shape in which the angle θ of the side walls 210 of the trench 212 is about 85° or more, and the bottom surface 211 of the trench 212 is flat without the generation of so-called microtrenches. Meanwhile, it was verified that microtrenches were generated on the bottom surface 211 of the trench 212 when the pressure was changed to 16.6 Pa. From these results, it may be said that the pressure inside the processing container 11 is favorably set to 4.7 Pa to 13.3 Pa.

As for the etching rate, it was verified that the etching rate was about 500 nm/min when the pressure was set to 4.7 Pa, about 610 nm/min when the pressure was set to 10.0 Pa, and about 700 nm/min when the pressure was set to about 13.3 Pa, and that the etching rate is improved as the pressure increases. This is presumed to be due to the increase of radicals or ions reaching the wafer W when the plasma density is improved as the pressure inside the processing container 11 increases.

Subsequently, a verification test was conducted for a case where among the gas mixture of SF₆/O₂/Ar, the O₂ gas was supplied at 5 sccm, the Ar gas was supplied at 880 sccm, and the flow rate of the SF₆ was changed to 3 scc, 4 sccm, 5, sccm, 10 sccm, and 20 sccm (Verification Test 3). In this case, the power of the high frequency power supply was set to 500 W, the set temperature of the wafer chuck 10 was 60° C., and the pressure inside the processing container 11 was set to 6.7 Pa.

As a result of Verification Test 3, it was verified that when the flow rate of SF₆ is changed to 4 sccm to 10 sccm, the trench 212 could be formed into an optimum shape, that is, the shape in which the angle θ of the side walls 210 of the trench 212 is about 85° or more, and the bottom surface 211 of the trench 212 is flat without the generation of so-called microtrenches. Meanwhile, it was verified that when the flow rate of the SF₆ is changed to 3 sccm and 20 sccm, microtrenches are generated on the bottom surface of the trench 212. From these results, it may be said that the flow rate ratio of the gas mixture of SF₆/O₂ is favorably set to about 2 to 1:1 to 1.3.

Further, a verification test was also conducted for a case where among the gas mixture of SF₆/O₂/Ar, the Ar gas was supplied at 880 sccm, the flow rates of the SF₆/O₂ were changed to 4/5 sccm, 8/10 sccm, and 16/20 sccm (Verification Test 4). In this case, the power of the high frequency power supply was set to 500 W, the set temperature of the wafer chuck 10 was 60° C., and the pressure inside the processing container 11 was 6.7 Pa.

As a result of Verification Test 4, it was verified that while the favorable trench shape could be obtained when the flow rates of SF₆/O₂ were changed to 4/5 sccm and 8/10 sccm, micro-trenches were generated on the bottom surface 211 of the trench 212 when the flow rates of SF₆/O₂ were changed to 16/20 sccm. From these results, it may be said that the sum of the flow rates of SF₆/O₂ is favorably about 18 sccm or less.

Subsequently, a verification test was also conducted for a case where among the gas mixture of SF₆/O₂/Ar, the SF₆ gas was supplied at 6 sccm, the O₂ gas was supplied at 3 sccm, and the flow rate of the Ar gas was changed to 220 sccm, 440 sccm, 660 sccm, 880 sccm, and 1,100 sccm (Verification Test 5). In this case, the power of the high frequency power supply was set to 1,000 W, the set temperature of the wafer chuck 10 was 60° C., and the pressure inside the processing container 11 was set to 13.3 Pa.

As a result of Verification Test 5, it was verified that while the favorable trench shape could be obtained when the flow rate of the Ar gas was 440 sccm or more, microtrenches were generated on the bottom surface 211 of the trench 212 when the flow rate of the Ar gas was 220 sccm. From the results, it may be said that since the lower limit for the flow rate of the Ar gas exists between about 220a sccm and 440 sccm, the flow rate of the Ar gas is favorably set to the lower limit or more. In addition, when the flow rate of the Ar gas was 440 sccm, the etching selection ratio of the SiC film 201 and the silicon oxide film 200 as an etching mask was about 5.2, and about 4.1 to 4.3 under other conditions. Thus, it was confirmed that the etching selection ratio is not proportional to the flow rate of the Ar gas, but a maximum point thereof exists. Further, from the results of Verification Test 5 and the results of above-described Verification Tests 3 and 4, it may be said that the flow rate ratio of the gas mixture of SF₆/O₂/Ar is favorably set to about 2 to 1:1 to 1.3:366.7 to 88.

Subsequently, a verification test was also conducted for a case where the gas mixture of SF₆/O₂/Ar was supplied at 6/7/440 sccm, and the SiF₄ gas was additionally mixed therewith at 12 sccm, 24 sccm, and 36 sccm (Verification Test 6). In this case, the power of the high frequency power supply was set to 1,250 W, the set temperature of the wafer chuck 10 was 60° C., and the pressure inside the processing container 11 was set to 13.3 Pa.

As a result of Verification Test 6, it was verified that while the favorable trench shape could be obtained when the flow rate of the SiF₄ gas was 12 sccm and 24 sccm, micro-trenches were generated on the bottom surface 211 of the trench 212 when the flow rate of the SiF₄ gas was 36 sccm. From these results, it may be said that the ratio of SF₆:SiF₄ is favorably set to a range of more than about 0 to 1:4. In addition, it was verified that the etching rate becomes, for example, about 900 nm/min to 1,050 nm/min by the mixture of the SiF₄ gas, and that the etching rate is largely improved, as compared to Verification Test 2 which did not add SiF₄.

Further, a verification test was also conducted for a case where a gas mixture of SF₆/O₂/He was used, instead of the gas mixture of SF₆/O₂/Ar (Verification Test 7). In this case, the flow rate of the gas mixture of SF₆/O₂/He was set to 6/3/880 sccm, the power of the high frequency power supply was set to 1,000 W, the set temperature of the wafer chuck 10 was set to 60° C., and the pressure inside the processing container 11 was set to 13.3 Pa.

As a result of Verification Test 7, the favorable trench shape could be obtained as in the case of using Ar gas. From this result, it was verified that He gas as another rare gas could be used, instead of Ar gas. Further, as described above, a rare gas other than Ar gas or He gas may be added, and according to the inventors of the present disclosure, it was verified that the same effect could also be obtained when the rare gas other than Ar gas or He gas is used. Further, according to the inventors of the present disclosure, the rare gases such as, for example, Ar gas and He gas may be added simultaneously. In other words, one or more of the rare gases such as, for example, Ar gas and He gas may be mixed with a processing gas containing SF₆ gas and O₂ gas so as to process the trench into a desired shape. As for the example of the case where the rare gases, for example, the Ar gas and the He gas are added simultaneously, the sum of the flow rates of the Ar gas and the He gas may be regarded as the flow rate of a rare gas, and the flow rate ratio of the gas mixture of SF₆/O₂/rare gas may be set in a range of about 2 to 1:1 to 1.3:366.7 to 88.

Further, a verification test was also conducted for a case where a gas mixture of HBr/NF₃/O₂ was used, instead of the gas mixture of SF₆/O₂/Ar. In this case as well, etching was performed on the SiC film 201 formed on the wafer W while using the silicon oxide film 200 as an etching mask, and the verification test was conducted to verify the influence of the relevant conditions for the etching on, for example, the shape or the etching rate of the etched SiC film 201. In this case, the thickness of the silicon oxide film 200 as a mask was set to 1,200 nm to 2,000 nm, and a target value of the etching depth of the SiC film was set to 2,000 nm. In addition, the used pitch (P of FIG. 4) of the silicon oxide film 200 formed as a mask on the SiC film 201 was 1 μm and 3 μm. In other words, each of a trench 212 having the width of 1 μm and a trench 212 having the width of 3 μm was formed on the SiC film 201 by etching. As the processing gas, the gas mixture of HBr/NF₃/O₂ was supplied at a flow rate ratio of 205/45/15, and the pressure inside the processing chamber 11, the power of the high frequency power supply 20, and the set temperature of the wafer chuck 10 were changed in a range of 3.3 Pa to 6.7 Pa, a range of 500 W to 1,500 W, and a range of 60° C. to 80° C., respectively. Further, verification tests were also conducted for a case where Ar was added to the processing gas and a case where etching was performed with the HBr gas alone.

As in the case of using the gas mixture of SF₆/O₂/Ar, the items verified in the verification tests were the angle θ of the side walls 210 of the trench 212, the shape of the bottom surface 211 of the trench 212, and the etching rate of the trench 212. The etching selection ratio of the trench 212 and the silicon oxide film 200 as an etching mask was also verified. The ratio of the depth of the trench 212 having the width of 1 μm and the depth of the trench 212 having the width of 3 μm was also verified, and the microloading effect was also inspected. As for a favorable shape of the trench 212, the angle θ of the side walls 210 of the trench 212 is about 85° or more, and the bottom surface 211 of the trench 212 is flat without the generation of so-called microtrenches. Further, since the SiC film has the crystal face orientation dependency depending on the electron mobility, the angle θ of the side walls 210 of the trench 212 is more favorably 90°.

First, a verification test was conducted for a case where the power of the high frequency power supply 20 was changed to 500 W, 650 W, and 1,500 W (Verification Test 8). In this case, the pressure inside the processing container 11 was set to 3.3 Pa (25 mTorr), the set temperature of the wafer chuck 10 was 60° C., and the Ar gas was not added to the processing gas.

FIG. 5 is a vertical sectional view schematically illustrating the shape of the trench 212 on the SiC film 201 in a case where the power of the high frequency power supply 20 is set to be higher than about 700 W. As a result of Verification Test 8, it was verified that when the power of the high frequency power supply 20 is set to about 1,500 W, the angle θ of the side walls 210 is below 85°, and microtrenches 220 are generated on the bottom surface 211 of the trench 212, in both the trench 212 having the width of 1 μm and the trench 212 having the width of 3 μm. Meanwhile, it was verified that when the power of the high frequency power supply 20 is set to about 700 W or less, for example, 500 W and 650 W in the present verification test, the trench 212 could be formed in an optimum shape as illustrated in FIG. 4, that is, the shape in which the angle θ of the side walls 210 of the trench 212 is about 85° or more, and the bottom surface 211 of the trench 212 is flat without the generation of so-called microtrenches. In the power of 500 W, the specific angle θ was about 90° for the trench 212 having the width of 1 μm and about 91° for the trench 212 having the width of 3 μm. In the power of 650 W, the specific angle θ was about 89° for the trench 212 having the width of 1 μm and about 90° for the trench 212 having the width of 3 μm.

In this case, it was also verified that in the power of 500 W, the etching rate of the SiC film 201 was about 178 nm/min for the trench 212 having the width of 1 μm and about 184 nm/min for the trench 212 having the width of 3 μm; in the power of 650 W, the etching rate was about 259 nm/min for the trench 212 having the width of 1 μm and about 263 nm/min for the trench 212 having the width of 3 μm; and in the power of 1,500 W, the etching rate was about 563 nm/min for the trench 212 having the width of 1 μm and about 565 nm/min for the trench 212 having the width of 3 μm. From these results, it was verified that when the power W increases, the etching rate is improved, but the shape of the trench 212 is deteriorated. According to the inventors of the present disclosure, the power of the high frequency is favorably set to 400 W or more in order to secure a required etching rate. Accordingly, it may be said that the power in the plasma etching is favorably set to 400 W to 700 W.

Further, from the above-described etching rates, it could also be verified that the ratio of the depth of the trench 212 having the width of 1 μm and the depth of the trench 212 having the width of 3 μm was about 97% in the power of 500 W and about 98% in the power of 650 W. Thus, according to the present disclosure, since the difference in the trench depth resulting from the microloading effect may be controlled to be very small, a trench may be favorably formed even in a pattern having low density.

Subsequently, the same etching was performed by adding the Ar gas to the processing gas and using the power of 1,500 W (Verification Test 9). In that case, the addition amount of the Ar gas was set to 300 sccm and 600 sccm. As a result of Verification Test 9 which added Ar, it was verified that the angle θ of the trench 212 was improved to about 87° for the addition amount of 300 sccm and about 87.5° for the addition amount of 600 sccm. Further, no microtrenches were generated on the bottom surface 211 of the trench 212. In addition, the etching rate was about 565 nm/min in both the cases where the Ar gas was added as described above, and exhibited no change depending on the small or large addition amount of the Ar gas.

From these results, it was verified that the deterioration of the trench shape could be suppressed by the addition of the Ar gas to the processing gas even when the etching is performed with the high power of 1,500. In other words, by performing the etching with the high power, the trench 212 having the favorable shape could be obtained while improving the etching rate.

In addition, the same etching was performed by supplying only the HBr gas as the processing gas and using the power of 1,500 W (Verification Test 10). In that case, the flow rate of the HBr gas was set to 250 sccm. As a result of Verification Test 10, the etching rate was about 530 nm/min for the trench 212 having the width of 1 μm and about 620 nm/min for the trench 212 having the width of 3 μm. From these results, it was verified that the etching could be performed at a favorable rate by using the HBr gas as the processing gas.

Subsequently, a verification test was conducted for a case where the set temperature of the wafer chuck 10 was to 60° C. and 80° C. (Verification Test 11). In this case, the power of the high frequency power supply was set to 650 W, the pressure inside the processing container 11 was set to 3.3 Pa (25 mTorr) Pa, and the Ar gas was not added to the processing gas.

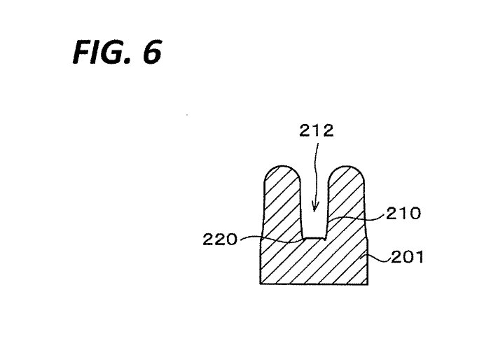

In Verification Test 11, it was verified that when the set temperature of the wafer chuck 10 is 60° C., the generation of the microtrenches 220 on the bottom surface of the trench 212 are substantially suppressed, and furthermore, an angle of about 86° or more could be obtained as for the angle θ of the side walls 210, as illustrated in FIG. 6, in both the trench 212 having the width of 1 μm and the trench 212 having the width of 3 μm. Further, it was verified that when the set temperature of the wafer chuck 10 was 80° C., the microtrenches 220 were further improved, as compared with the case of 60° C.

Further, it was verified that when the set temperature of the wafer chuck 10 was 60° C. and 80° C., the etching selection ratio was about 4.5 and 3.6 in the respective cases, and that the selection ratio was lowered as the set temperature of the wafer chuck 10 increases. From these results, it is presumed that the changes in the etching selection ratio and the trench shape are in the trade-off relationship with the change of the set temperature of the wafer chuck 10.

Subsequently, a verification test was conducted for a case where the pressure inside the processing container 11 was changed in a range of 3.3 Pa to 6.7 Pa (25 mTorr to 45 mTorr) (Verification Test 12). In this case, the power of the high frequency power supply was set to 1,500 W, the set temperature of the wafer chuck 10 was 60° C., and the Ar gas was not added to the processing gas.

In Verification Test 12, the etching rate was about 645 nm/min for the trench 212 having the width of 1 μm and about 655 nm/min for the trench 212 having the width of 3 μm, in both the case where the pressure inside the processing container 11 was changed to 3.3 Pa and the case where the pressure was changed to 6.7 Pa, which exhibited no significant difference. Meanwhile, it was verified that the etching selection ratio of the SiC film 201 and the silicon oxide film 200 as an etching mask was about 3.7 to 3.8 for the case where the pressure inside the processing container 11 was set to 3.3 Pa, and about 6.0 to 6.4 for the case where the pressure was set to 6.7 Pa. From these results, it could be verified that the etching selection ratio could increase as the pressure during the etching was set high. Further, it was verified that the angle θ of the side walls 210 of the trench 212 was about 87° at the pressure of 3.3 Pa and about 86° at the pressure of 6.7 Pa, and that the shape of the trench 212 was improved as the pressure was set low.

Subsequently, a verification test was conducted for a case where the gas mixture of HBr/SF₆/O₂ was used, instead of the gas mixture of HBr/NF₃/O₂ (Verification Test 13). The flow rates of HBr/SF₆/O₂ were, for example, 250/15/3 sccm, respectively. In this case, the power of the high frequency power supply was set to 2,000 W, the set temperature of the wafer chuck 10 was 40° C., the pressure inside the processing container 11 was set to 2.0 Pa (15 mTorr), and the Ar gas was not added to the processing gas.

As a result of Verification Test 13 in which etching was performed by using the gas mixture of HBr/SF₆/O₂, it was verified that the etching rate was about 465 nm/min for the trench 212 having the width of 1 μm and about 561 nm/min for the trench 212 having the width of 3 μm, and that the favorable etching rate could be obtained.

From the foregoing, it will be appreciated that although various embodiments of the present disclosure have been described herein, the present disclosure is not limited thereto. It is obvious that a person skilled in the art is able to conceive various changes or modifications within the scope of the technical idea defined in the claims. Accordingly, it is understood that the changes or modifications also belong to the technical scope of the present disclosure.

### DESCRIPTION OF SYMBOL

1: plasma etching apparatus
10: wafer chuck
11: processing container
12: grounding line
13: susceptor
14: insulating member
15: conducting member
16: lift mechanism
17: bellows
20: high frequency power supply
21: matcher
30: focus ring
31: baffle plate
32: exhaust pipe
40: upper electrode
41: gas supply pipe
50: ring magnet
100: controller
W: wafer
U: processing space
V: gas diffusion chamber

What is claimed is:

1. A method for plasma etching a SiC film having an etching mask formed thereon within a processing container, the method comprising:
supplying a gas mixture obtained by mixing a processing gas containing SF₆ gas and O₂ gas and a rare gas with each other into the processing container, to etch the SiC film by plasma of the gas mixture,
wherein the etching is performed by using a magnetron RIE apparatus.

2. The method of claim 1, wherein a ratio of the SF₆ gas:the O₂ gas:the rare gas of the gas mixture is 2 to 1:1 to 1.3:366.7 to 88,
a pressure inside the processing container is kept at 4.7 Pa to 13.3 Pa during the etching, and
the plasma of the gas mixture is generated by a high frequency power of 500 W to 1,300 W.

3. The method of claim 1, wherein SiF₄ gas is additionally mixed with the gas mixture.

4. The method of claim 3, wherein a ratio of SF₆:SiF₄ of the gas mixture is more than 0 to 1:4.

5. A method for plasma etching a SiC film having an etching mask formed thereon within a processing container, the method comprising:
supplying a processing gas containing HBr gas into the processing container, to etch the SiC film by plasma of the processing gas,
wherein a pressure inside the processing container is kept at 2.0 Pa to 13.3 Pa during the etching, the etching is performed by using a magnetron RIE apparatus, and the plasma of the processing gas is generated by a high frequency power of 400 W to 2,000 W.

6. The method of claim 5, wherein NF₃ gas and O₂ gas are additionally mixed with the processing gas.

7. The method of claim 6, wherein a ratio of the HBr gas:the NF₃ gas:the O₂ gas is 13 to 20:3 to 5:1.

8. The method of claim 5, wherein SF₆ gas and O₂ gas are additionally mixed with the processing gas.

9. The method of claim 8, wherein a ratio of the HBr gas:the SF₆ gas:the O₂ gas of the processing gas is 13 to 20:0 to 3:1.

10. The method of claim 6, wherein Ar gas is additionally mixed with the processing gas.

11. The method of claim 5, wherein the SiC film is formed on a substrate, and etching is performed in a state where the substrate is placed on a placement table, and a temperature of the placement table is kept at 60° C. to 80° C.

12. The method of claim 5, wherein the high frequency power for generating the plasma of the processing gas is 400 W to 700 W.

13. The method of claim 1, wherein the etching mask is a silicon oxide film.

14. The method of claim 5, wherein the etching mask is a silicon oxide film.
